(19) United States
(12) Patent Application Publication
(10) Pub. No.: US 2016/0313379 A1
(43) Pub. Date: Oct. 27, 2016

(54) VOLTAGE WARNING SYSTEM

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: WEI ZHANG, WuHan (CN); CHUN-SHENG CHEN, New Taipei (TW)

(21) Appl. No.: 14/716,255

(22) Filed: May 19, 2015

(30) Foreign Application Priority Data
Apr. 23, 2015 (CN) 201510196243.1

(51) Int. Cl. G01R 19/165

(52) U.S. Cl. CPC G01R 19/1659

(57) ABSTRACT

A voltage warning system includes a voltage dividing module configured to be coupled to an output voltage from a power module; a first switch module is coupled to the voltage dividing module; a second switch module is coupled to the first switch module; and a warning module is coupled to the second switch module. The voltage dividing module is configured to divide the output voltage, and the divided voltage is configured to switch on and off the first switch module. The first switch module is configured to activate and deactivate the second switch module. The second switch module is configured to activate and deactivate the warning module. When the output voltage is lower than a setting voltage, the divided voltage activates the warning module to sound alarm via the first switch module and the second switch module.

### FIELD

The subject matter herein generally relates to voltage warning systems.

### BACKGROUND

A voltage conversion circuit is generally embedded in a motherboard of an electronic device, and the voltage conversion circuit outputs direct current voltage to supply power for a number of electronic components secured to the motherboard.

### BRIEF DESCRIPTION OF THE DRAWINGS

Implementations of the present technology will now be described, by way of example only, with reference to the attached figures.

FIG. 1 is a block diagram of an embodiment of a voltage warning system.

FIG. 2 is a circuit diagram of a first embodiment of the voltage warning system of FIG. 1.

FIG. 3 is a circuit diagram of a second embodiment of the voltage warning system of FIG. 1.

FIG. 4 is a circuit diagram of a third embodiment of the voltage warning system of FIG. 1.

FIG. 5 is a circuit diagram of a fourth embodiment of the voltage warning system of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series, and the like.

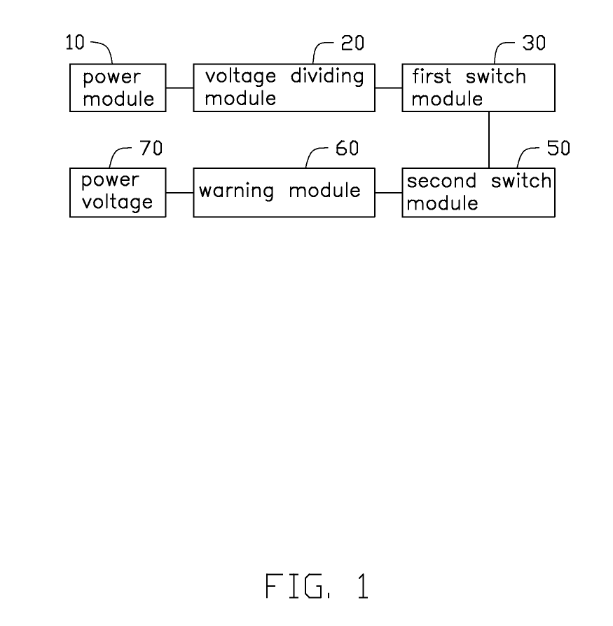

FIG. 1 illustrates a voltage warning system for controlling a voltage output from a power module 10 in accordance with an embodiment. The voltage warning system can include a voltage dividing module 20, a first switch module 30, a second switch module 50, and a warning module 60.

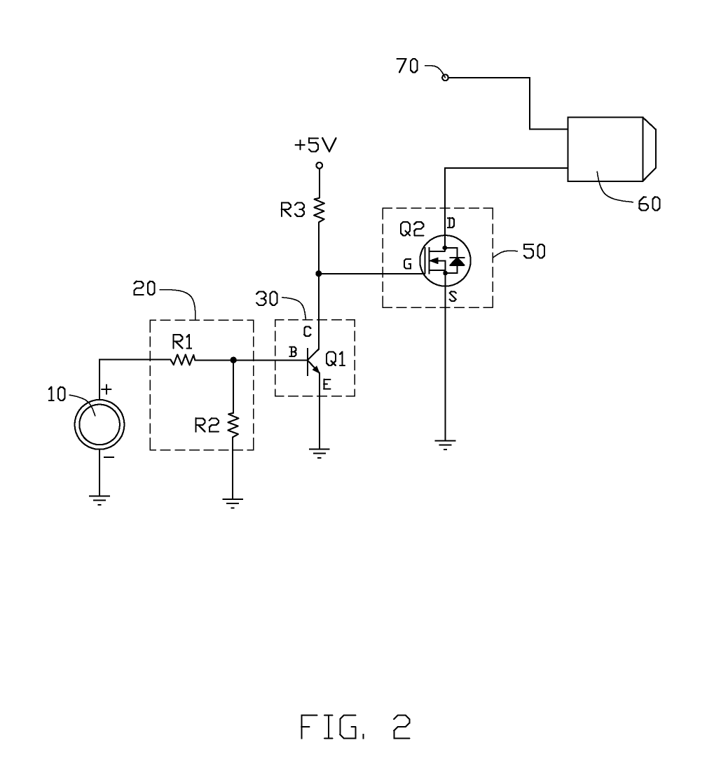

FIG. 1 and FIG. 2 illustrate that the voltage dividing module 20 is coupled to an output port of the power module 10 and includes a coupling resistor R1 and a voltage dividing resistor R2. A first end of the coupling resistor R1 is coupled to the output port of the power module 10. A second end of the coupling resistor R1 is coupled to a first end of the voltage dividing resistor R2. A second end of the voltage dividing resistor R2 is grounded.

The first switch module 30 can include a first transistor Q1 coupled to the first end of the voltage dividing resistor R2. The voltage of the first end of the voltage dividing resistor R2 is configured to switch the first transistor Q1 on or off. In at least one embodiment, the first transistor Q1 is a triode, the base B of the first transistor Q1 is coupled to the first end of the voltage dividing resistor R2, the emitter E of the first transistor Q1 is grounded, and the collector C of the first transistor Q1 is coupled to a high level voltage, such as +5V, via a pull-up resistor R3.

The second switch module 50 can include a second transistor Q2 coupled to the first transistor Q1. The first transistor Q1 is configured to switch the second transistor Q2 on or off. In at least one embodiment, the second transistor Q2 is a field effect transistor (FET), the gate electrode G of the second transistor Q2 is coupled to the collector C of the first transistor Q1, the source electrode S of the second transistor Q2 is grounded, and the drain electrode D of the second transistor Q2 is coupled to a negative pole of the warning module 60. In at least one embodiment, the first transistor Q1 is an npn-type triode, and the second transistor Q2 is an n-type FET.

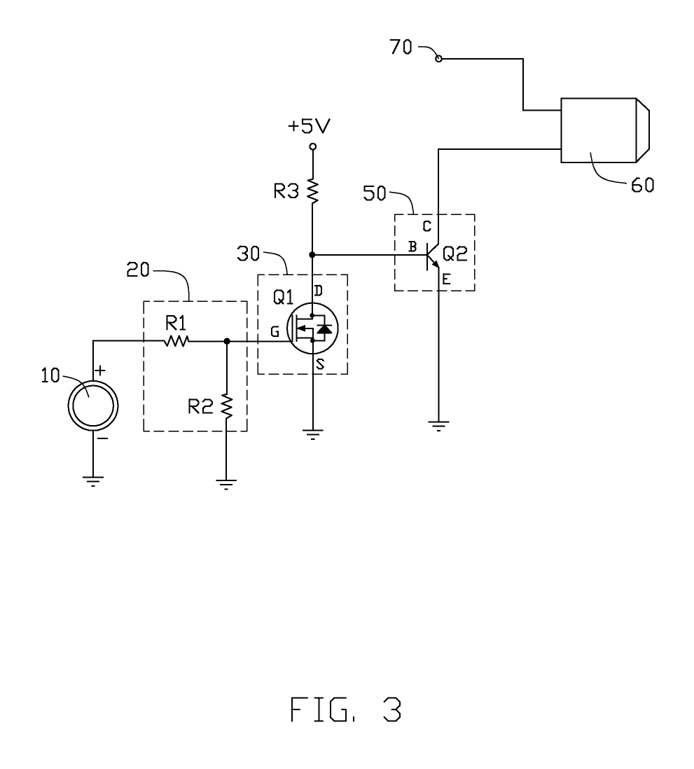

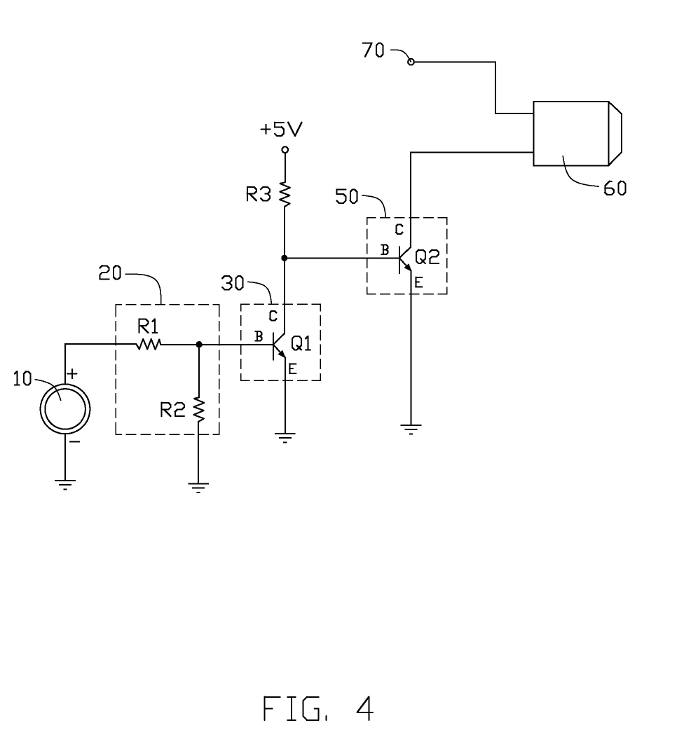

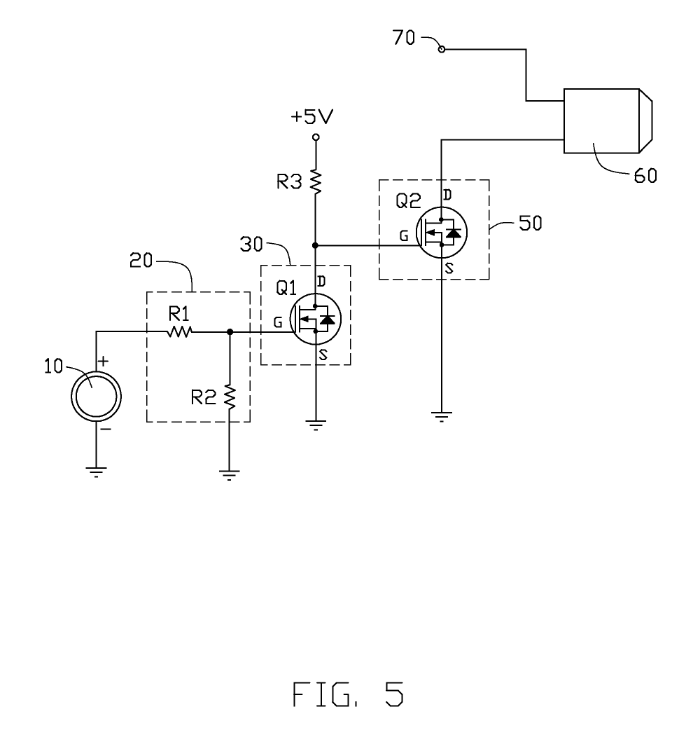

FIGS. 3-5 illustrate that in other embodiments, the first transistor Q1 can be a FET, the second transistor Q2 can be a triode, the first transistor Q1 can be a pnp-type triode, and the second transistor Q2 can be a p-type FET.

A positive pole of the warning module 60 is coupled to a power voltage 70. In at least one embodiment, the warning module 60 is a buzzer.

In operation, when the output voltage from the power module 10 is greater than or equal to a setting voltage, the voltage of the first end of the voltage dividing resistor R2 is a high level, the high level voltage switches on the first transistor Q1, the collector C of the first transistor Q1 has a low level voltage, the low level voltage switches off the second transistor Q2, and the negative pole of the warning module 60 is cut off, to deactivate the warning module 60.

When the output voltage from the power module 10 is lower than the setting voltage, the voltage of the first end of the voltage dividing resistor R2 is a low level, the low level voltage switches off the first transistor Q1, the collector C of the first transistor Q1 has a high level voltage, the high level voltage switches on the second transistor Q2, and the negative pole of the warning module 60 is switched on, to activate the warning module 60 to sound alarm as reminder that the output voltage from the power module 10 is lower than the setting voltage.

The embodiments shown and described above are only examples. Many details are often found in the art such as the other features of a voltage warning system. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A voltage warning system comprising:
a power module having an output voltage;
a voltage dividing module couplable to the output voltage and is configured to divide the output voltage;
a first switch module coupled to the voltage dividing module, wherein the divided voltage is configured to switch the first switch module on and off;
a second switch module coupled to the first switch module, wherein the first switch module is configured to activate and deactivate the second switch module; and
a warning module coupled to the second switch module, wherein the second switch module is configured to activate and deactivate the warning module;
wherein when the output voltage is lower than a setting voltage, the divided voltage activates the warning module to alarm via the first switch module and the second switch module.

2. The voltage warning system of claim 1, wherein when the output voltage is lower than the setting voltage, the divided voltage switches off the first switch module and switches on the second switch module, which activates the warning module; and when the output voltage is greater than or equal to the setting voltage, the divided voltage switches on the first switch module and switches off the second switch module, which deactivates the warning module.

3. The voltage warning system of claim 2, wherein when the first switch module is switched off, the first switch module switches on the second switch module, and when the first switch module is switched off, the first switch module switches off the second switch module.

4. The voltage warning system of claim 1, wherein the voltage dividing module comprises a coupling resistor and a voltage dividing resistor, a first end of the coupling resistor is coupled to the output voltage, a second end of the coupling resistor is coupled to a first end of the voltage dividing resistor, and a second end of the voltage dividing resistor is grounded.

5. The voltage warning system of claim 4, wherein the first switch module comprises a first transistor coupled to the first end of the voltage dividing resistor.

6. The voltage warning system of claim 5, wherein the first transistor is a triode, the base of the first transistor is coupled to the first end of the voltage dividing resistor, the emitter of the first transistor is grounded, and the collector of the first transistor is coupled to a high level voltage via a pull-up resistor.

7. The voltage warning system of claim 6, wherein the second switch module comprises a second transistor coupled to the emitter of the first transistor.

8. The voltage warning system of claim 7, wherein the second transistor is a field effect transistor (FET), the gate electrode of the second transistor is coupled to the collector of the first transistor, the source electrode of the second transistor is grounded, and the drain electrode of the second transistor is coupled to a negative pole of the warning module.

9. The voltage warning system of claim 8, wherein the warning module is a buzzer, a positive pole of the warning module is coupled to a power voltage.

10. The voltage warning system of claim 7, wherein the first transistor is an npn-type triode, and the second transistor is an n-type FET.

11. A voltage warning system comprising:
a power module having an output voltage;
a voltage dividing module couplable to the output voltage and is configured to divide the output voltage;
a first switch module coupled to the voltage dividing module, wherein the divided voltage is configured to switch the first switch module on and off;
a second switch module coupled to the first switch module, wherein the first switch module is configured to activate and deactivate the second switch module; and
a warning module coupled to the second switch module, wherein the second switch module is configured to activate and deactivate the warning module;
wherein the first switch module is coupled between the voltage dividing module and the second switch module, the second switch module is coupled between the first switch module and the warning module, and when the output voltage is lower than a setting voltage, the divided voltage activates the warning module to alarm via the first switch module and the second switch module.

12. The voltage warning system of claim 11, wherein when the output voltage is lower than the setting voltage, the divided voltage switches off the first switch module and switches on the second switch module, which activates the warning module; and when the output voltage is greater than or equal to the setting voltage, the divided voltage switches on the first switch module and switches off the second switch module, which deactivates the warning module.

13. The voltage warning system of claim 12, wherein when the first switch module is switched off, the first switch module switches on the second switch module, and when the first switch module is switched off, the first switch module switches off the second switch module.

14. The voltage warning system of claim 11, wherein the voltage dividing module comprises a coupling resistor and a voltage dividing resistor, a first end of the coupling resistor is coupled to the output voltage, a second end of the coupling resistor is coupled to a first end of the voltage dividing resistor, and a second end of the voltage dividing resistor is grounded.

15. The voltage warning system of claim 14, wherein the first switch module comprises a first transistor coupled to the first end of the voltage dividing resistor.

16. The voltage warning system of claim 15, wherein the first transistor is a triode, the base of the first transistor is coupled to the first end of the voltage dividing resistor, the emitter of the first transistor is grounded, and the collector of the first transistor is coupled to a high level voltage via a pull-up resistor.

17. The voltage warning system of claim 16, wherein the second switch module comprises a second transistor coupled to the emitter of the first transistor.

18. The voltage warning system of claim 17, wherein the second transistor is a field effect transistor (FET), the gate electrode of the second transistor is coupled to the collector of the first transistor, the source electrode of the second transistor is grounded, and the drain electrode of the second transistor is coupled to a negative pole of the warning module.

19. The voltage warning system of claim 18, wherein the warning module is a buzzer, a positive pole of the warning module is coupled to a power voltage.

20. The voltage warning system of claim 17, wherein the first transistor is an npn-type triode, and the second transistor is an n-type FET.
